(19) United States
(12) Patent Application Publication
(10) Pub. No.: US 2013/0049214 A1
(43) Pub. Date: Feb. 28, 2013

(54) METHOD OF PROCESSING AT LEAST ONE DIE AND DIE ARRANGEMENT

(71) Applicants: Ivan Nikitin, Regensburg (DE); Joachim Mahler, Regensburg (DE)

(72) Inventors: Ivan Nikitin, Regensburg (DE); Joachim Mahler, Regensburg (DE)

(73) Assignee: INFINEON TECHNOLOGIES AG, Neubiberg (DE)

(21) Appl. No.: 13/219,747

(22) Filed: Aug. 29, 2011

(51) Int. Cl. H01L 21/768; H01L 23/48

(52) U.S. Cl. 257/774; 438/675; 257/E23.011; 257/E21.586

(57) ABSTRACT

In various embodiments, a method of processing at least one die may include: forming at least one placeholder element over at least one contact pad of at least one die; forming a die embedding layer to at least partially embed the at least one die and the at least one placeholder element; removing the at least one placeholder element to form at least one opening in the at least one die embedding layer and expose the at least one contact pad of the at least one die; filling the at least one opening with electrically conductive material to electrically contact the at least one contact pad of the at least one die.

### TECHNICAL FIELD

Various embodiments relate generally to a method of processing at least one die and to a die arrangement.

### BACKGROUND

A central element in current chip packaging technologies such as chip embedding technologies is the boring of holes into the embedding material (e.g. laminate) and the (mostly galvanic) refilling of the holes for realization of metallic terminal contacts (“vias”). Forming the holes by means of boring may become increasingly difficult with increasing length of the holes. In particular, a central issue may be the focusing depth for the borings, which may often lead to strong damage of a chip's contact pads which, in turn, may render the device (chip) inoperative. In worst case, this may lead to chip failure in the field and thus to customer returns.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a diagram illustrating a method of processing at least one die in accordance with an embodiment;

FIG. 1B shows a schematic cross-sectional view of a die arrangement in accordance with another embodiment;

FIG. 1C illustrates coverage of a contact pad's surface area with a terminal contact's base area in accordance with another embodiment;

FIG. 2A to FIG. 2H show schematic cross-sectional views illustrating various processing stages in a method of processing at least one die in accordance with another embodiment;

FIG. 3A to FIG. 3I show schematic cross-sectional views illustrating various processing stages in a method of processing at least one die in accordance with another embodiment;

FIG. 4A to FIG. 4F show schematic cross-sectional views illustrating various processing stages in a method of processing at least one die in accordance with another embodiment;

FIG. 5 shows a die arrangement in accordance with another embodiment;

FIG. 6A to FIG. 6F show schematic cross-sectional views illustrating various processing stages in a method of processing at least one die in accordance with another embodiment.

FIG. 7 shows a die arrangement in accordance with another embodiment.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. The following detailed description therefore is not to be taken in a limiting sense, and the scope of the present invention is defined by the appended claims.

Various embodiments are provided for methods, and various embodiments are provided for devices. It will be understood that basic properties of the methods also hold for the devices and vice versa. Therefore, for sake of brevity, duplicate description of such properties may be omitted.

The term “at least one” as used herein may be understood to include any integer number equal to or greater than one, i.e. “one”, “two”, “three”, . . . , etc.

The term “a plurality” as used herein may be understood to include any integer number equal to or greater than two, i.e. “two”, “three”, “four”, . . . , etc.

Unless otherwise indicated, the term “layer” as used herein may be understood to include embodiments where a layer is configured as a single layer, as well as embodiments where a layer is configured as a layer sequence or layer stack including a plurality of sublayers. The individual sublayers of a layer sequence or layer stack may, for example, include or may be made of different materials, or at least one of the sublayers may include or may be made of the same material as another one of the sublayers.

The term “over” as used herein may be understood to include both embodiments where a first layer (structure, element, etc.) is formed (disposed, located, arranged, etc.) on a second layer (structure, element, etc.), with direct physical contact to the second layer (structure, element, etc.), as well as embodiments where a first layer (structure, element, etc.) is formed (disposed, located, arranged, etc.) above a second layer (structure, element, etc.), with one or more intervening layers (structures, elements, etc.) between the first layer (structure, element, etc.) and the second layer (structure, element, etc.).

The terms “contact pad” or “pad” as used herein may be understood to include, for example, a designated metallization area at the surface of a die or chip that may be used to electrically contact the die from/to the outside.

The terms “placeholder element”, “placeholder structure”, “placeholder” or “spacer” as used herein may be understood to refer to an element or structure that may be temporarily formed to reserve (in other words, keep free) some room or space for a certain other element, structure, layer, etc. to be formed later on (i.e. after the placeholder element has been removed again). To this end, the placeholder element may be formed at a location where the other element, structure, layer etc. shall be formed later on. Clearly, by means of the placeholder element some room or space may be temporarily “blocked” from being occupied or filled. In other words, it may be prevented that this room or space will be occupied or filled with material of other elements, structures or layers until the placeholder element is removed. For example, in accordance with various embodiments described herein, a placeholder element may be formed over a contact pad where a terminal contact (herein also referred to as “via”) shall be formed later. In accordance with various embodiments, a placeholder element may be formed before a die embedding layer is formed. Thus, the room or space occupied by the placeholder element may remain free from material of the die embedding layer when the die embedding layer is formed. After formation of the die embedding layer, the placeholder element may be removed again, thereby clearly leaving a gap (opening or hole) in the die embedding layer. This gap may then be filled with electrically conductive material (e.g. metal) to form the terminal contact. The shape of the terminal contact (“via”) may clearly be defined by or correspond to the shape of the placeholder element.

A central element in current chip packaging technologies such as chip embedding technologies may be the boring of holes into the embedding material (e.g. laminate) and the (mostly galvanic) refilling of the holes for realization of metallic terminal contacts (“vias”). With increasing length of the holes this may become increasingly difficult. In particular, a central issue may be the focusing depth for the borings, which may often lead to strong damage of a chip's contact pads which, in turn, may render the device (chip) inoperative. In the worst case, this may lead to chip failure in the field and thus to customer returns.

Current approaches to avoid damage of the chip's contact pads when boring holes into the embedding material (e.g. laminate) may for example include formation of a thick front side metallization layer (e.g. thick front side copper (Cu) metallization) as the last layer on the chip.

In order to realize terminal contacts and a “redistribution” for a chip or chips, holes may usually be bored into the embedding material (e.g. laminate) above the chips, for example by means of a laser, and the holes may then be filled completely with metal (e.g. Cu) by means of galvanic deposition. Problems that may occur in this connection may, for example, include or be related to:

exact positioning accuracy of the laser or of the LDI (laser direct imaging) structuring;

setting of the laser's borehole depth;

destruction of the contact pads located on the chip(s), down to which the laser bores through the laminate;

high expenditure of time for a serial process;

high process expenditure in order to create a thick metallization (e.g. having a thickness of equal to or greater than about 5 μm);

lasing of chip embedding material (e.g. laminate) may produce carbon black particles, which may cause unwanted electrically conductive filaments in the device.

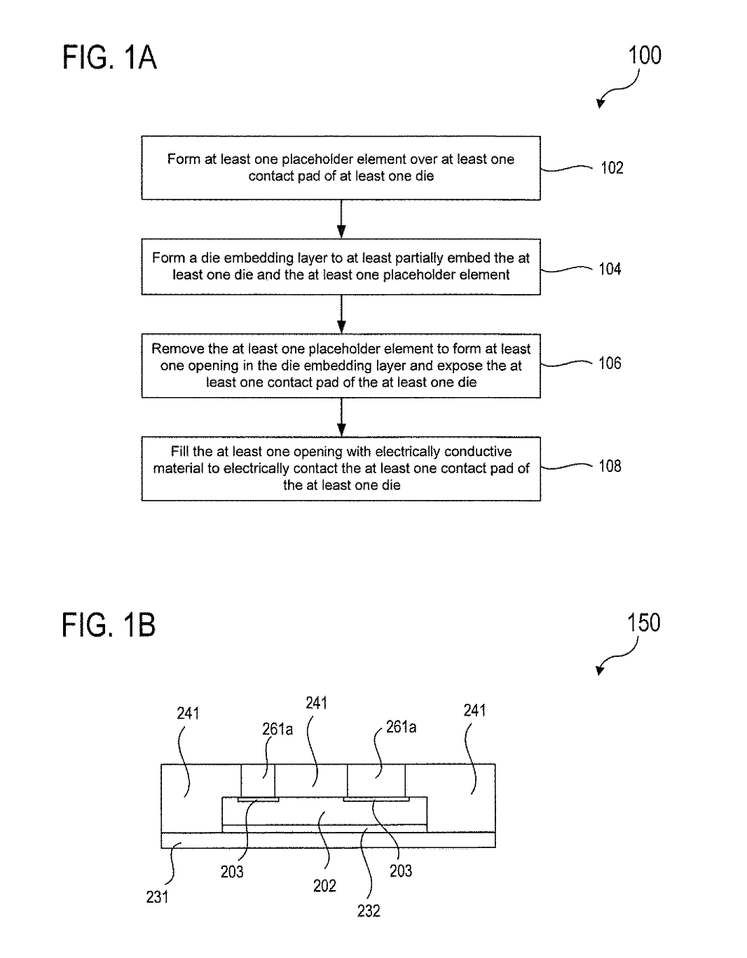

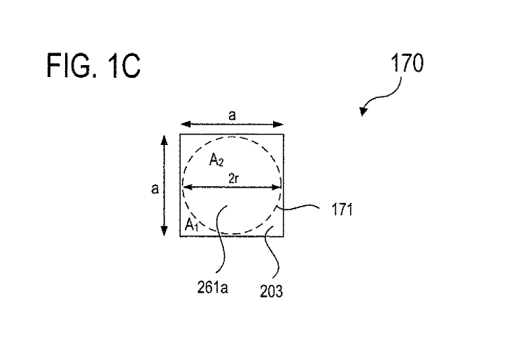

FIG. 1A shows a diagram 100 illustrating a method of processing at least one die in accordance with an embodiment.

In 102, at least one placeholder element may be formed over at least one contact pad of at least one die. In accordance with some embodiments, a plurality of contact pads may be formed over a contact pad. In accordance with some embodiments, a plurality of placeholder elements may be formed over a plurality of contact pads. The number of contact pads and the number of placeholder elements per contact pad may be chosen arbitrarily. That is, each of the contact pads may have an arbitrary number of placeholder elements (one, two, three, . . . , etc.) formed over the contact pad. The number of placeholder elements may be the same or may be different for different contact pads. In accordance with some embodiments, a plurality of placeholder elements may be formed over a plurality of contact pads of a plurality of dies.

In 104, a die embedding layer may be formed to at least partially embed the at least one die and the at least one placeholder element. In other words, a layer of die embedding material may be formed such that the at least one die and the at least one placeholder element are at least partially embedded in the die embedding material. In some embodiments, the die embedding layer may enclose or surround the at least one die and/or the at least one placeholder element.

In 106, the at least one placeholder element may be removed to form at least one opening in the die embedding layer and expose the at least one contact pad of the at least one die. In other words, the at least one placeholder element may be removed such that at least one opening or hole remains in the die embedding layer and such that the at least one contact pad, e.g. an upper surface of the at least one contact pad, is exposed. The location of the at least one opening or hole may correspond to the location of the at least one placeholder element. The shape of the at least one opening or hole may correspond to the shape of the at least one placeholder element.

In 108, the at least one opening may be filled with electrically conductive material to electrically contact the at least one contact pad of the at least one die. In other words, the at least one opening or hole may be filled with electrically conductive material such that the electrically conductive material contacts the at least one contact pad, e.g. the exposed upper surface of the at least one contact pad.

In accordance with various embodiments, the at least one contact pad may include or may be made of a metal such as, for example, copper or aluminum, or a metal alloy such as, for example, an alloy containing copper and/or aluminum in accordance with some embodiments, although any other suitable metals or metal alloys may be possible as well in accordance with other embodiments. In accordance with some embodiments, it may, for example, be possible that the at least one contact pad includes a base metallization layer (e.g. a copper layer or an aluminum layer) and one or more reinforcement layers disposed over the base metallization layer, for example a nickel/palladium/gold layer stack or a nickel-phosphorous/palladium/gold layer stack in accordance with some embodiments, although any other suitable layer arrangements may be possible for the at least one contact pad as well, as will be readily understood by those skilled in the art.

In accordance with various embodiments, the at least one placeholder element may include or may be made of a material or materials that may be removed without leaving residues on the die embedding layer. In other words, the at least one placeholder element may include or may be made of a material or materials that may allow for a residue-free removal of the at least one placeholder element.

For example, in accordance with some embodiments, the at least one placeholder element may include or may be made of a material or materials that may reduce or substantially eliminate sticking of the placeholder element to the die embedding layer.

For example, in accordance with one embodiment, the at least one placeholder element may include or may be made of polytetrafluoroethylene (PTFE) (“Teflon”).

In accordance with another embodiment, the at least one placeholder element may include or may be made of steel, for example having an anti-stick coating (in other words, a coating that may reduce or substantially eliminate sticking of the placeholder element to the die embedding layer) in accordance with some embodiments (e.g. PTFE coated steel).

In accordance with another embodiment, the at least one placeholder element may include or may be made of a ceramic material, for example having an anti-stick coating in accordance with some embodiments (e.g. a PTFE coated ceramic material).

In accordance with another embodiment, the at least one placeholder element may include or may be made of a UV transparent plastic material (i.e. a plastic material that is transparent for ultraviolet (UV) light), for example having an anti-stick coating in accordance with some embodiments (e.g. a PTFE coated UV transparent plastic material).

In accordance with another embodiment, the at least one placeholder element may include or may be made of a thermally deactivatable adhesive (herein also referred to as thermal release adhesive).

In accordance with another embodiment, the at least one placeholder element may include or may be made of an adhesive that may be deactivated by light (e.g. visible light or UV light).

In accordance with another embodiment, the at least one placeholder element may include or may be made of a magnetic material (for example, a paramagnetic or ferromagnetic material (e.g. metal or metal alloy), e.g. a ferrous material, e.g. a ferrous alloy such as steel).

The at least one placeholder element may have an arbitrary shape. The shape of the placeholder element may clearly define or correspond to the shape of a terminal contact (“via”) that may be formed by the electrically conductive material filling the opening or hole in the die embedding layer.

For example, in accordance with various embodiments, the at least one placeholder element may have the shape of a (e.g. cylindrical) column or pillar, although other shapes may be possible as well. A lateral cross-section of the column or pillar may have an arbitrary shape, for example, an elliptical or circular shape, or a polygonal shape (e.g. rectangular, quadratic, triangular, hexagonal, etc.).

A lateral cross-sectional diameter of the at least one placeholder element (e.g. column) may correspond to a lateral cross-sectional diameter of a terminal contact (“via”) to be formed later. In accordance with some embodiments, the lateral cross-sectional diameter of the at least one placeholder element (e.g. column) may, for example, be in the range from about 10 μm to about 500 μm, for example in the range from about 10 μm to about 100 μm in some embodiments, e.g. in the range from about 10 μm to about 50 μm in some embodiments, e.g. in the range from about 20 μm to about 30 μm in some embodiments, although other values of the diameter may be possible as well.

It has to be noted that in accordance with some embodiments, the lateral cross-sectional diameter or area of the placeholder element does not need to be constant across the entire height of the placeholder element but may vary with the height. In other words, the cross-sectional diameter or area of the placeholder element may vary in a direction perpendicular to a main processing surface of the at least one die or the at least one contact pad. The placeholder element may, for example, have a shape with (continuously or stepwise) increasing or decreasing cross-sectional diameter or area such as, for example, a cone shape, a truncated cone shape, a pyramid shape, a step pyramid shape, or any other suitable shape.

In accordance with some embodiments, the placeholder element may be formed such that a base area of the placeholder element that contacts the contact pad is located entirely within the boundaries of the contact pad. In other words, the placeholder element may be formed such that its base area does not protrude over the contact pad.

In accordance with various embodiments, the placeholder element may be formed such that its base area covers 70% to 100% of the contact pad area, for example at least 80% in accordance with some embodiments, e.g. at least 90% in accordance with some embodiments, for example without protruding over the contact pad.

In accordance with some embodiments, forming the at least one placeholder element may be carried out at a wafer level processing stage. In other words, in accordance with some embodiments, forming the at least one placeholder element may be carried out in a processing stage, in which the die may be (still) part of a wafer, for example before a die singulation (or dicing) takes place.

Illustratively, in accordance with some embodiments, forming the at least one placeholder element may be carried out in a front-end processing stage and/or using one or more front-end processing steps such as, for example, photolithographic steps. Forming the at least one placeholder element using front-end processing steps may, for example, have the effect that the accuracy of front-end processes or processing steps (which may be typically very high, for example in the nanometer range) may be exploited. Thus, it may be possible to achieve a very precise alignment (in other words, positioning accuracy) of the placeholder element (and thus of a terminal contact that may be defined by the placeholder element) to the contact pad. Thus, it may, for example, be possible to realize terminal contacts (“vias”) that may use a higher percentage of the contact pad area (e.g. about 70% or more of the contact pad area, as described above) than may be possible with conventional processes. For example, in conventional processes it may be necessary to provide contact pads with a relatively large area overhead in order to make sure that a terminal contact actually “lands” on the contact pad, for example due to a relatively low positioning accuracy of a laser that is used to bore holes into the chip embedding material. In accordance with various embodiments described herein, the alignment accuracy (or positioning accuracy) of the terminal contacts may be improved (for example, by making use of the very high-accuracy of front-end processes that may be used to form the holes in the chip embedding material) so that the area overhead of a contact pad may be substantially reduced or even eliminated.

In accordance with some embodiments, forming the at least one placeholder element may include forming (e.g. depositing) a placeholder element layer over the at least one die and patterning the placeholder element layer to form the at least one placeholder element.

In accordance with some embodiments, the placeholder element layer may be a photopatternable layer, in other words a layer including or being made of a material that may be patterned using a photolithographical process. For example, in accordance with some embodiments, the photopatternable layer may include or may be made of a photopatternable polymer material, e.g. a photoresist.

In accordance with another embodiment, patterning the placeholder element layer may be effected by means of a laser.

In accordance with some embodiments, the at least one die may be part of a wafer that may include a plurality of dies, and forming (e.g. depositing) the placeholder element layer over the at least one die may include forming (e.g. depositing) the placeholder element layer over the wafer. Thus, the placeholder element layer may be formed (e.g. deposited) over the plurality of dies. In this case, patterning the placeholder element layer may, for example, result in a plurality of placeholder elements corresponding to the contact pads of the plurality of dies.

In accordance with some embodiments, the wafer may be diced after patterning the placeholder element layer. This may result in a plurality of singulated dies, with each die including one or more placeholder elements corresponding to the die's contact pad(s).

In accordance with another embodiment, forming the at least one placeholder element may include: providing a carrier layer and a placeholder element layer disposed over the carrier layer; patterning the placeholder element layer to have the at least one placeholder element; applying the carrier layer with the patterned placeholder element layer to the die to transfer the at least one placeholder element onto the at least one contact pad of the die; removing the carrier layer.

In accordance with an embodiment, the placeholder element layer may, for example, be a photopatternable layer (e.g. a photopatternable polymer layer, e.g. a photoresist layer), and patterning the placeholder element layer may, for example, be achieved using a photolithographical process, as described above. In accordance with another embodiment, the placeholder element layer may be patterned using a laser. Alternatively, the placeholder element layer may include or may be made of any other suitable material that may be patterned.

A thickness of the placeholder element layer may correspond to the height of the at least one placeholder element to be formed from the placeholder element layer.

In accordance with some embodiments, the height of the at least one placeholder element may be in the micrometer range, for example in the range from several micrometers to several tens of micrometers in accordance with some embodiments, for example in the range from about 10 μm to about 50 μm in accordance with some embodiments, for example in the range from about 20 μm to about 30 μm in accordance with some embodiments, although other values of the height may be possible as well in accordance with other embodiments.

The carrier layer may, for example, include or may be made of any suitable carrier material.

In accordance with some embodiments, an adhesive layer may be disposed on the placeholder element layer, i.e. on a surface of the placeholder element layer facing away from the carrier layer. For example, in accordance with one embodiment, an adhesive polymer foil may be provided, the adhesive polymer foil including a carrier layer, a polymer layer (which may serve as the placeholder element layer) disposed on the carrier layer, and an adhesive layer disposed on the polymer layer. The polymer layer (together with the adhesive layer) of the foil may be patterned to have the at least one placeholder element, and the foil with the patterned polymer layer (and adhesive layer) may be attached to the die (or to the plurality of dies) such that the at least one placeholder element is located over the at least one contact pad. Subsequently, the carrier layer may be removed such that the patterned polymer layer (i.e. the at least one placeholder element) remains at the locations where terminal contacts are to be formed later.

In accordance with some embodiments, the at least one die may be part of a wafer that may include a plurality of dies, and applying the carrier layer with the patterned placeholder element layer to the at least one die may include applying the carrier layer with the patterned placeholder element layer to the wafer. In this way, a plurality of placeholder elements may be formed over a plurality of contact pads of a plurality of dies.

In accordance with some embodiments, the wafer may be diced after removing the carrier layer. Thus, a plurality of singulated dies may be obtained, each die including one or more placeholder elements formed over one or more contact pads of the respective die.

In accordance with some embodiments, forming the at least one placeholder element may be carried out at a package level processing stage. In other words, the at least one placeholder element may be formed in a back-end processing stage where the die or dies may be packaged, for example after singulation of the dies.

In accordance with some embodiments, forming the at least one placeholder element may be effected by means of dispensing placeholder element material (for example an adhesive material, e.g. a thermal release adhesive, alternatively other suitable dispensable materials) onto the at least one contact pad.

In accordance with another embodiment, forming the at least one placeholder element may be effected using a screen printing process.

In accordance with another embodiment, forming the at least one placeholder element may be effected using a lamination process.

In accordance with other embodiments, forming the at least one placeholder element may be effected using other suitable processes.

In accordance with some embodiments, the die embedding layer may be formed using a lamination process. In accordance with some embodiments, the die embedding layer may include or may be made of a laminate material (for example, a resin material, e.g. an epoxy resin (e.g. filled with glass fiber)), although other suitable embedding materials such as, for example, a mold compound may be possible as well in accordance with other embodiments. In other words, in accordance with some embodiments the die embedding layer may include or may be a laminate layer (e.g. a laminate foil in accordance with an embodiment).

In accordance with other embodiments, the die embedding layer may be formed using other suitable processes such as, for example, molding.

In accordance with some embodiments, removing the at least one placeholder element may include or may be achieved by heating the placeholder element (or the at least one die with the at least one placeholder element), for example in case that the at least one placeholder element includes or is made of a thermally deactivatable adhesive. In this case, the at least one placeholder element may, for example, be heated to a temperature where the material (or materials) of the placeholder element (e.g. the thermal release adhesive) loses its adhesive force, for example to a temperature equal to or greater than about 150° C. in accordance with some embodiments (other temperature values may be possible as well; the temperature may, for example, depend on the specific material(s) used for the placeholder element).

In accordance with some embodiments, removing the at least one placeholder element may include or may be achieved by exposing the placeholder element to light (e.g. UV light in accordance with an embodiment), for example in case that the placeholder element includes or is made of an adhesive that may be deactivated by light.

In accordance with some embodiments, removing the at least one placeholder element may include or may be achieved using a magnet, for example in case that the placeholder element includes or is made of a magnetic material.

In accordance with some embodiments, removing the at least one placeholder element may include orienting the at least one die such that gravity may assist in the placeholder element slipping out of the die embedding layer. Clearly, in accordance with some embodiments, removing the at least one placeholder element may be achieved or assisted by orienting the die (or the plurality of dies, e.g. a wafer including the die or plurality of dies) “upside down” so that the placeholder element or elements may slip out or fall out of the die embedding layer due to its/their own weight. This “upside down” orientation may, for example, be carried out during and/or after heating the placeholder element (e.g. in case that the placeholder element includes or is made of a thermally deactivatable adhesive), or during and/or after exposing the placeholder element to light (e.g. in case that the placeholder element includes or is made of an adhesive that may be deactivated by exposure to light).

In accordance with some embodiments, removing the at least one placeholder element may include or may be effected by means of a selective etch process. In other words, the at least one placeholder element may be removed by selectively etching the material of the placeholder element.

In accordance with some embodiments, the electrically conductive material that is used to fill the at least one opening may include or may be a metal or metal alloy such as for example copper or an alloy containing copper in accordance with some embodiments, although any other suitable metals or metal alloys such as, for example, silver or silver alloys, nickel or nickel alloys, aluminum or aluminum alloys, or others, may be possible as well in accordance with other embodiments. In accordance with some embodiments, it may, for example, be possible that the filling of the at least one opening includes an inner or base metallization (for example, including or being made of copper) in combination with an outer or shell metallization (for example, including or being made of silver and/or gold) serving, for example, as corrosion protection.

In accordance with an embodiment, filling the at least one opening with the electrically conductive material (e.g. metal) may include or may be achieved by galvanic deposition of the electrically conductive material. In other words, the at least one opening may be filled with the electrically conductive material (for example metal, e.g. copper) by means of a galvanic deposition process.

In accordance with another embodiment, filling the at least one opening with the electrically conductive material may include or may be achieved by introducing a metal paste into the at least one opening.

In accordance with other embodiments, the at least one opening may be filled with the electrically conductive material (e.g. metal) using other suitable processes, e.g. other suitable deposition processes.

In accordance with some embodiments, the die may be attached to a die carrier, and, before forming the die embedding layer, at least one additional placeholder element may be formed over the die carrier, wherein forming the die embedding layer may include forming the die embedding layer such that it additionally embeds the at least one additional placeholder element at least partially.

In accordance with some embodiments, a plurality of dies may be attached to the die carrier, and a plurality of placeholder elements may be formed over the contact pads of the dies, and a plurality of additional placeholder elements may be formed over the die carrier, for example between the dies or next to a die or dies.

In accordance with some embodiments, the at least one additional placeholder element (or the plurality of additional placeholder elements) may be removed to form at least one additional opening (or a plurality of openings) in the die embedding layer over the die carrier, and the at least one additional opening (or the plurality of additional openings) may be filled with the electrically conductive material to electrically contact the die carrier.

FIG. 1B shows a schematic cross-sectional view of a die arrangement 150 in accordance with another embodiment. The die arrangement 150 may, for example, be obtained using a method of processing at least one die in accordance with one or more embodiments described herein, and some or all of the elements of the die arrangement 150 may, for example, be formed or configured in accordance with one or more embodiments described herein.

In accordance with various embodiments, the die arrangement 150 may include at least one die 202 (a single die 202 is shown in FIG. 1B as an example, however, more than one die 202 may be provided in accordance with other embodiments). The at least one die 202 may include at least one contact pad 203 (two contact pads 203 are shown as an example, however a smaller or larger number of contact pads 203 may be provided in accordance with other embodiments).

In accordance with various embodiments, the die arrangement 150 may include at least one terminal contact 261a (“via”) (two terminal contacts 261a are shown as an example, however a smaller or larger number of terminal contacts 261a may be provided in accordance with other embodiments). The at least one terminal contact 261a may be disposed over the at least one contact pad 203 of the at least one die 202.

In accordance with various embodiments, the die arrangement 150 may include a die embedding layer 241. The die embedding layer 241 may at least partially embed the at least one die 202 and the at least one terminal contact 261a. In accordance with some embodiments, the die embedding layer 241 may include or may be made of a laminate material, e.g. an epoxy resin (e.g. filled with glass fiber) in accordance with an embodiment, although other suitable embedding materials may be possible as well in accordance with other embodiments. For example, in accordance with some embodiments, the die embedding layer 241 may include or may be made of a mold compound.

In accordance with various embodiments, the at least one terminal contact 261a may have been formed by forming at least one placeholder element over the at least one contact pad 203 of the at least one die 202, forming the die embedding layer 241 to at least partially embed the at least one die 202 and the at least one placeholder element, removing the at least one placeholder element to form at least one opening in the die embedding layer 241 and expose the at least one contact pad 203 of the at least one die 202, and filling the at least one opening with electrically conductive material to electrically contact the at least one contact pad 203 of the at least one die 202, as described and shown herein in connection with various embodiments.

In the embodiment shown in FIG. 1B, two terminal contacts 261a are shown as an example, and each of the terminal contacts 261a may have been formed by forming a respective placeholder element over the respective contact pad 203 before forming the die embedding layer 241, removing the placeholder elements after the die embedding layer 241 has been formed so that an opening is in each case formed over the respective contact pad 203, and filling the openings with electrically conductive material (i.e. with material of the terminal contacts 261a). In accordance with other embodiments, a different number of terminal contacts 261a may be provided, and the number of placeholder elements may be chosen accordingly.

In accordance with various embodiments, the die embedding layer 241 may be free from carbon black particles.

Illustratively, the die arrangement 150 of FIG. 1B may be obtained using a method of processing at least one die in accordance with one or more embodiments described herein, wherein one or more openings may be formed in the die embedding layer 241 by forming one or more placeholder elements before the die embedding layer 241 is formed, and removing the placeholder elements again after the die embedding layer 241 has been formed, as described herein. Thus, in accordance with various embodiments, the openings (or holes) in the die embedding layer 241 may be formed without boring, in particular without using a laser.

Thus, in accordance with various embodiments it may be avoided that electrically conductive carbon black particles are generated at or in the die embedding layer 241 (for example at or near side walls of the openings or holes in the die embedding layer 241), which may be the case in a conventional process where a laser is used to bore holes into the die embedding material. In many cases, the die embedding material may, for example, include or may be a laminate based on organic materials or compounds (e.g. an epoxy resin) that contain carbon (C). When a laser is used to bore holes into the laminate, heat may be generated in the laminate, which may lead to a carbonization process, during which electrically conductive carbon black particles may be created. The electrically conductive carbon black particles may lead to the formation of unwanted electrically conductive filaments in the device (sometimes also referred to as conductive anodic filaments (CAF)).

In the die arrangement 150 shown in FIG. 1B, which may be obtained by using a method of processing at least one die in accordance with one or more embodiments described herein, the generation of electrically conductive carbon black particles may be avoided so that the occurrence of conductive filaments may be substantially reduced or even eliminated.

In accordance with some embodiments, the die arrangement 150 may include a die carrier 231, and the at least one die 202 may be attached to the die carrier 231, for example by means of an adhesive layer 232 (as shown), or by soldering, or using other suitable techniques.

In accordance with some embodiments, a base area of the at least one terminal contact 261a may cover at least 70% of the area of the underlying contact pad 203, e.g. at least 80% in accordance with some embodiments, e.g. at least 90% in accordance with some embodiments, without protruding over the contact pad 203.

This is illustrated in FIG. 1C, which shows a schematic plan view 170 of a contact pad 203 (having a quadratic surface shape with edge length a as an example) with surface area A₁ (=a² in the example shown), and a terminal contact 261a (having a circular cross-section with constant cross-sectional diameter 2*r as an example) disposed over the contact pad 203 and having a base area A₂ (=π*r² in the example shown).

As shown, in accordance with some embodiments, a base area of the terminal contact 261a (indicated by the dashed circle 171) may be located entirely within the boundaries of the contact pad 203. In other words, it may be possible that the base area 171 does not protrude over the contact pad 203.

As described above, the ratio A₂:A₁ (i.e. percental coverage of the contact pad's surface area A₁ with the base area A₂ of the terminal contact) may be in the range from about 0.7 (=70%) to 1 (=100%) in accordance with some embodiments, e.g. at least 0.7 (=70%) in accordance with some embodiments, e.g. at least 0.8 (=80%) in accordance with some embodiments, e.g. at least 0.9 (=90%) in accordance with some embodiments.

In FIG. 1C, a contact pad 203 with quadratic surface shape and a terminal contact 261a with circular cross-section have been shown merely as an example; other surface shapes of the contact pad 203 (e.g. rectangular, circular, elliptical, etc.) and/or other cross-sectional shapes (e.g. rectangular, quadratic, elliptical, etc.) of the terminal contact 261a or the terminal contact 261a's base area may be possible as well in accordance with some embodiments. In each case, the coverage of the contact pad 203's surface area with the terminal contact 261a's base area may be as described above.

In accordance with some embodiments, a roughness of an interface between the die embedding layer 241 and the at least one terminal contact 261a, which clearly may be defined by a surface roughness of the at least one opening 251's sidewall or sidewalls, may be lower than in conventional arrangements where the openings/holes are formed by laser boring. For example, in accordance with some embodiments, the surface roughness of the sidewall or sidewalls of the at least one opening 251 may be equal to or lower than about 5 μm, for example equal to or lower than about 1 μm in accordance with some embodiments, which may lead to a correspondingly low interface roughness between the die embedding layer 241 and the at least one terminal contact 261a.

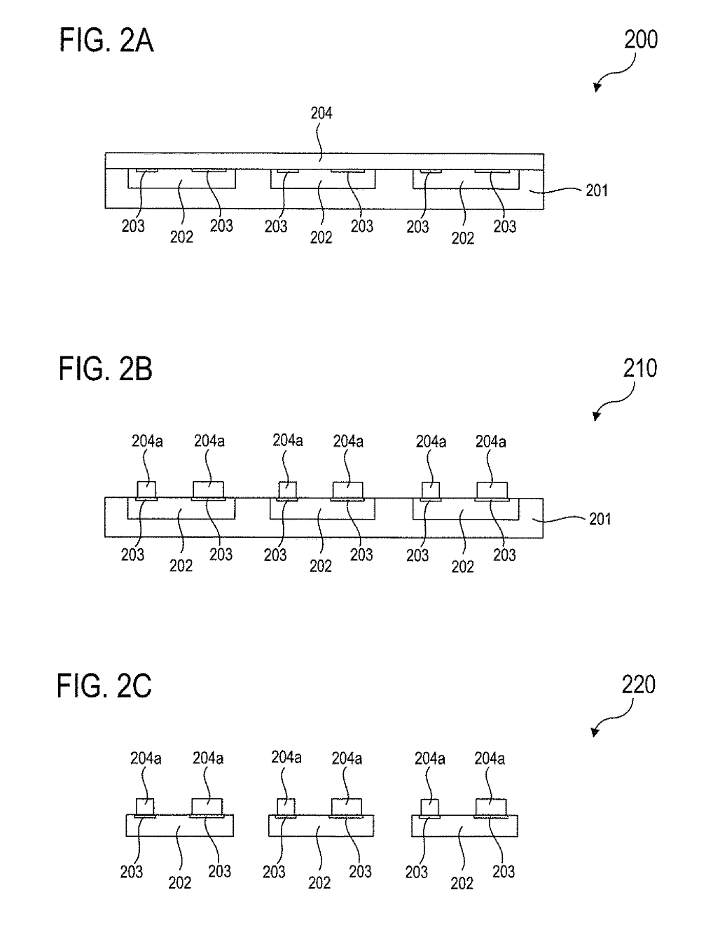

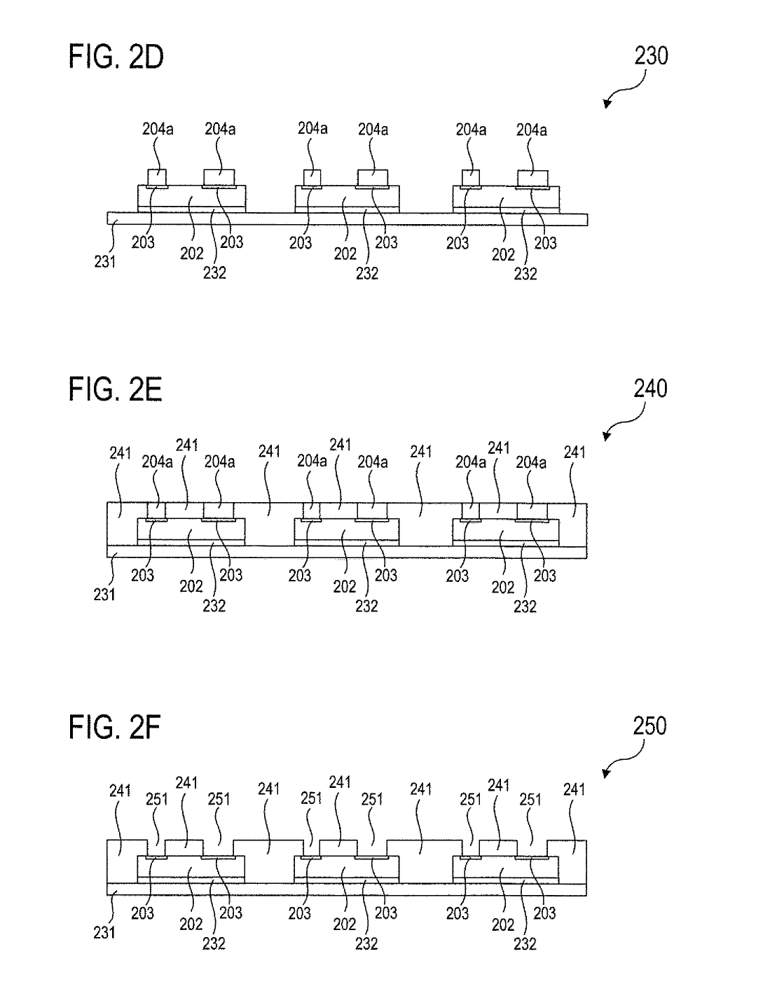

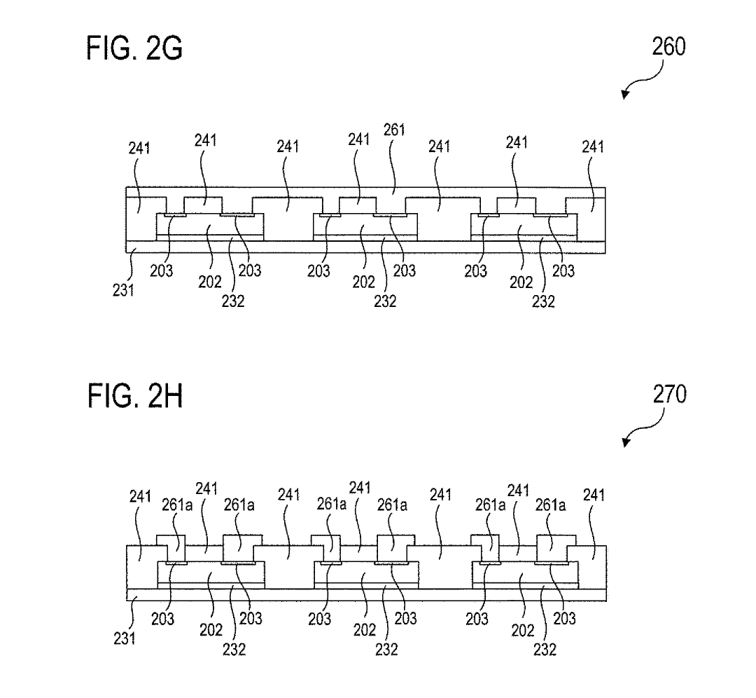

FIG. 2A to 2H show schematic cross-sectional views illustrating various processing stages in a method of processing at least one die in accordance with another embodiment.

FIG. 2A shows, in a view 200, that a placeholder element layer 204 may be formed over a wafer 201 including a plurality of dies 202.

The placeholder element layer 204 may include or may be made of a material that may be patterned. For example, in accordance with some embodiments, the placeholder element layer 204 may be a photopatternable layer (in other words, a layer that may be patterned by means of photolithography), for example a photopatternable polymer layer (e.g. a photo resist layer) in accordance with one embodiment.

The wafer 201 may include one or more dies 202; three dies 202 are shown as an example in FIG. 2A, however any other number of dies 202 may be possible in accordance with other embodiments.

Each die 202 may include one or more contact pads 203. Two contact pads 203 per die 202 are shown as an example in FIG. 2A, however any other number of contact pads 203 may be possible in accordance with other embodiments. The number of contact pads 203 may be the same for each die 202 (as shown), or may be different. The contact pads 203 of a die 202 may have different sizes (as shown) or may have the same size. The contact pads 203 may, for example, serve to make electrical contact to one or more integrated circuit (IC) elements (e.g. transistors, diodes, etc.) of a respective die 202 (not shown).

The placeholder element layer 204 may cover the dies 202 including the contact pads 203, as shown.

FIG. 2B shows, in a view 210, that the placeholder element layer 204 may be patterned (for example, by means of photolithography, alternatively using other suitable processes) so that a plurality of placeholder elements 204a (also referred to as spacers) are formed.

The placeholder elements 204a are formed over the contact pads 203 of the dies 202. In the embodiment shown, a single placeholder element 204a is formed in each case over a respective one of the contact pads 203. However, the number of placeholder elements 204a per contact pad 203 may be greater than one for one or more of the contact pads 203 in accordance with other embodiments.

In accordance with some embodiments, the placeholder elements 204a may have a columnar shape (e.g. a cylindrical shape with circular cross-section), however any other shape may be possible in accordance with other embodiments.

In accordance with some embodiments, the placeholder elements 204a may be formed such that their base area does not protrude over the respective contact pad 203, as shown. In accordance with some embodiments, the base area of a placeholder element 204a may, for example, cover about 70% or more of the area of the respective contact pad 203.

FIG. 2C shows, in a view 220, that the dies 202 may be singulated after the placeholder elements 204a have been formed. In other words, a die singulation process (also referred to as dicing) may be carried out to separate the dies 202 after the placeholder elements 204a have been formed. Clearly, in accordance with the embodiment shown, the placeholder elements 204a may be formed at a wafer level processing stage before singulation of the dies 202.

FIG. 2D shows, in a view 230, that the singulated dies 202 may be attached (in other words, mounted) to a carrier 231 (also referred to as die carrier), for example by means of an adhesive layer 232 (as shown), or by means of soldering, or using some other suitable die attaching technique. The carrier 231 may, for example, include or may be made of an electrically conductive material. For example, in accordance with some embodiments, the carrier 231 may be a metal carrier or metal plate, e.g. a lead frame, in accordance with some embodiments. In accordance with other embodiments, the carrier 231 may include or may be made of an electrically insulating material.

FIG. 2E shows, in a view 240, that a die embedding layer 241 may be formed such that the dies 202 and the placeholder elements 204a may be at least partially embedded in the die embedding layer 241. In accordance with various embodiments, the die embedding layer 241 may include or may be made of a suitable embedding material such as, for example, a laminate material in accordance with one embodiment, or a mold compound in accordance with another embodiment, or any other suitable embedding material in accordance with other embodiments. For example, in accordance with an embodiment, the die embedding layer 241 may be a foil that may be laminated onto the carrier 231 and the dies 202. The die embedding layer 241 may be formed such that an upper surface of the placeholder elements 204a may be exposed, as shown.

In the embodiment shown in FIG. 2E, the die embedding layer 241 is shown such that an upper surface of the die embedding layer 241 is flush with an upper surface of the placeholder elements 204a. In this context it has to be noted that, in accordance with some embodiments, it may be possible that the die embedding layer 241 is initially formed such that it may cover the upper surface of the placeholder elements 204a, and that a part of the die embedding layer 241 that covers the upper surface of the placeholder elements 204a may subsequently be removed (e.g. using a laser, or using etch chemistry, alternatively using other suitable processes) to expose the upper surface of the placeholder elements 204a.

FIG. 2F shows, in a view 250, that the placeholder elements 204a may be removed (for example, by means of a selective etch process in accordance with an embodiment) such that openings (or holes) 251 may be formed in the die embedding layer 241. The openings (or holes) 251 may be located above the contact pads 203 of the dies 202 such that the contact pads 203 may be exposed, as shown. In other words, the locations of the openings (holes) 251 may correspond to the locations of the contact pads 203.

FIG. 2G shows, in a view 260, that the openings 251 may be filled with a layer 261 of electrically conductive material (e.g. a metal such as, for example, copper), for example by means of galvanic deposition or introducing a metal paste (alternatively, by means of some other suitable process), such that the contact pads 203 of the dies 202 may be electrically contacted.

FIG. 2H shows, in a view 270, that the layer 261 of electrically conductive material may be patterned (e.g. by means of a photolithographical etch process) such that terminal contacts 261a may be formed that may electrically contact the contact pads 203. As shown, each contact pad 203 may be contacted by a respective terminal contact 261a and the terminal contacts 261a may be separated from one another. Illustratively, FIG. 2H shows a die arrangement in accordance with an embodiment.

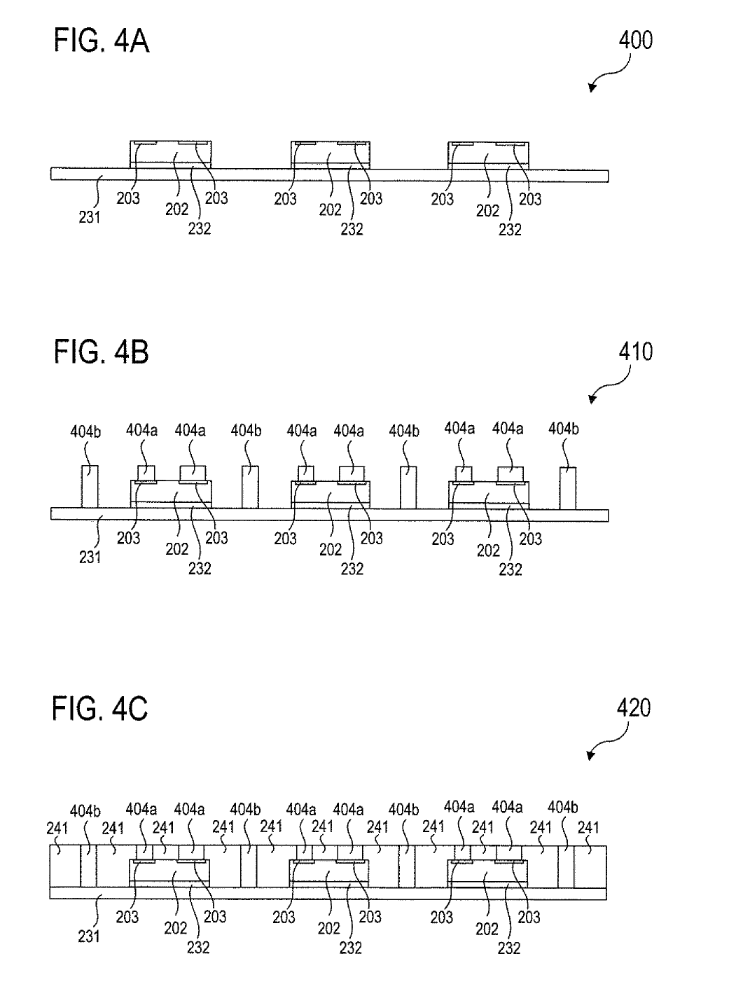

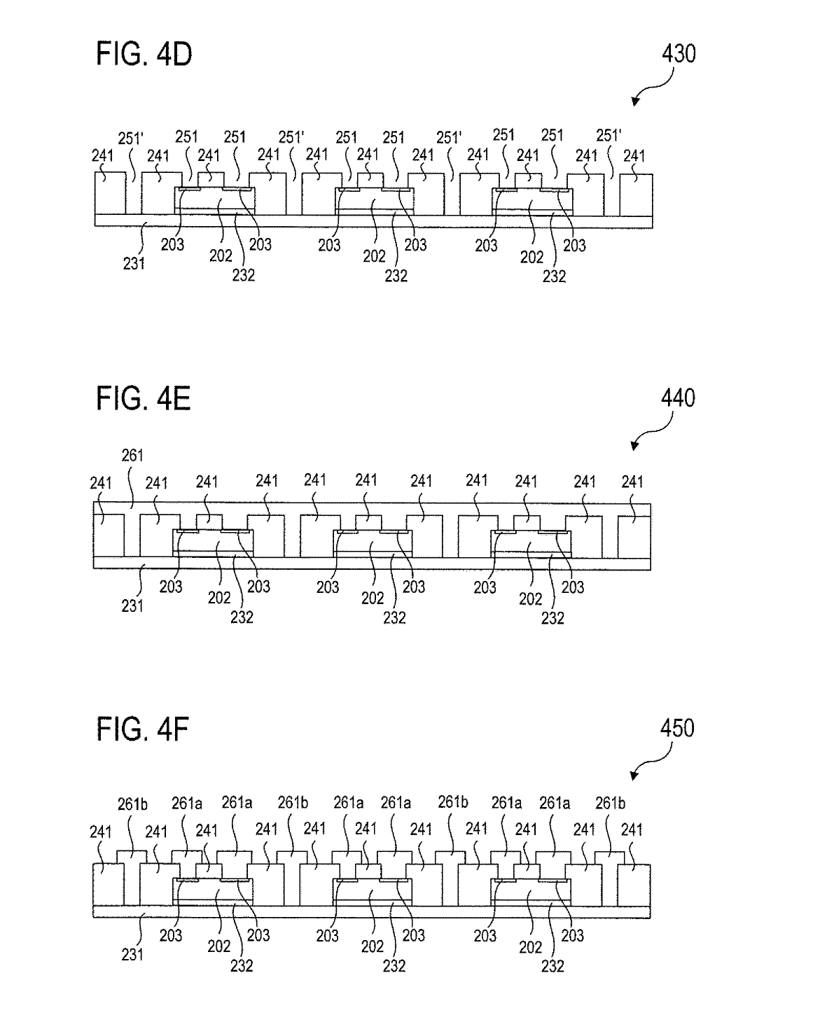

In accordance with some embodiments, the dies 202 may subsequently be singulated. The singulated dies may, for example, be connected to a circuit board via the terminal contacts 261a and, in accordance with some embodiments, via additional electrical contacts formed over the carrier 231 between the dies 202 or next to the dies 202 (not shown, see e.g. FIG. 4F). In accordance with some embodiments, the additional electrical contacts may, for example, be formed by forming additional placeholder elements over the carrier 231 between the dies or next to the dies 202 (e.g. after attaching the dies 202 to the carrier 231), forming the die embedding layer 241 to additionally embed the additional placeholder elements, removing the additional placeholder elements to form additional openings over the carrier 231, and filling the additional openings with the layer 261 of electrically conductive material and patterning the layer 261 accordingly (not shown, compare FIG. 4B to FIG. 4F).

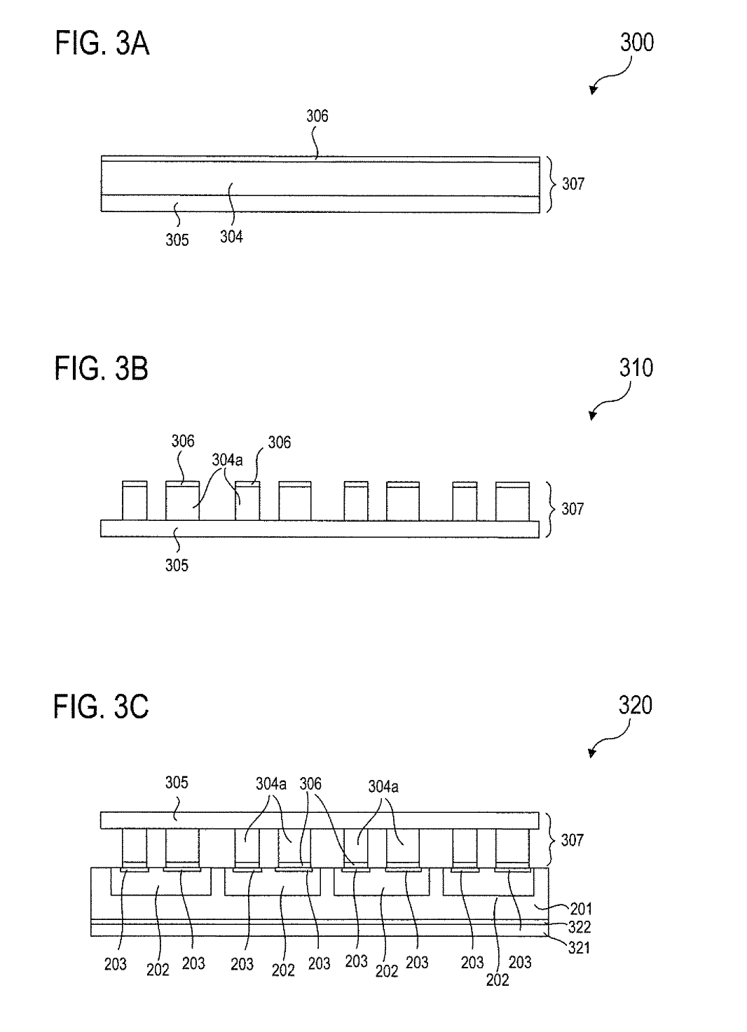

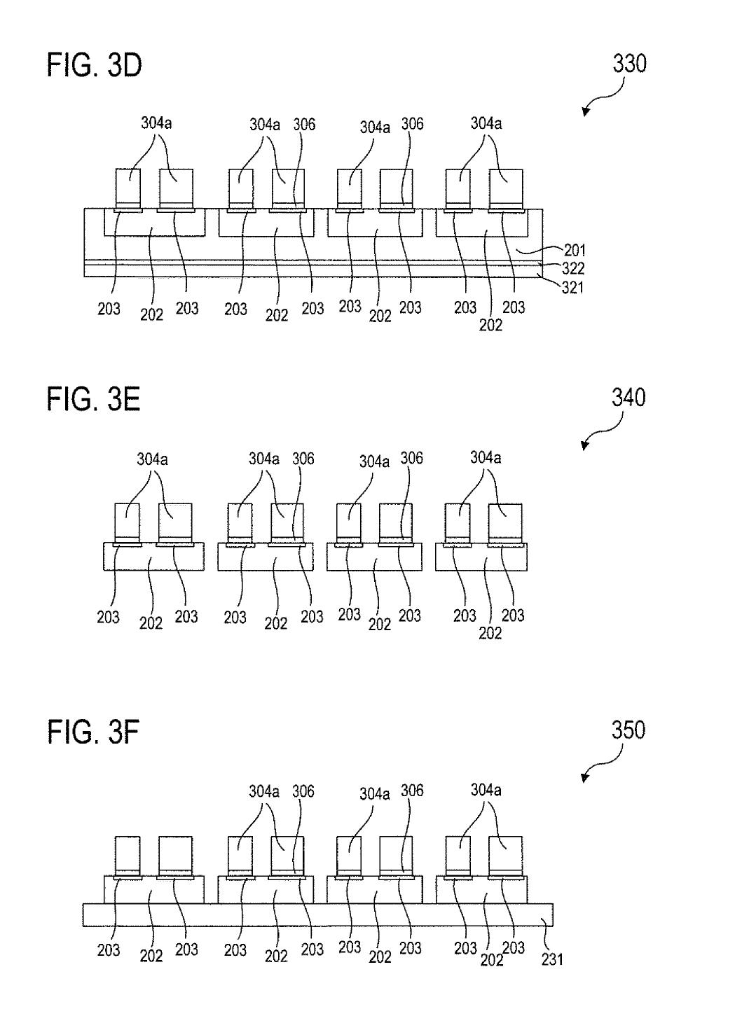

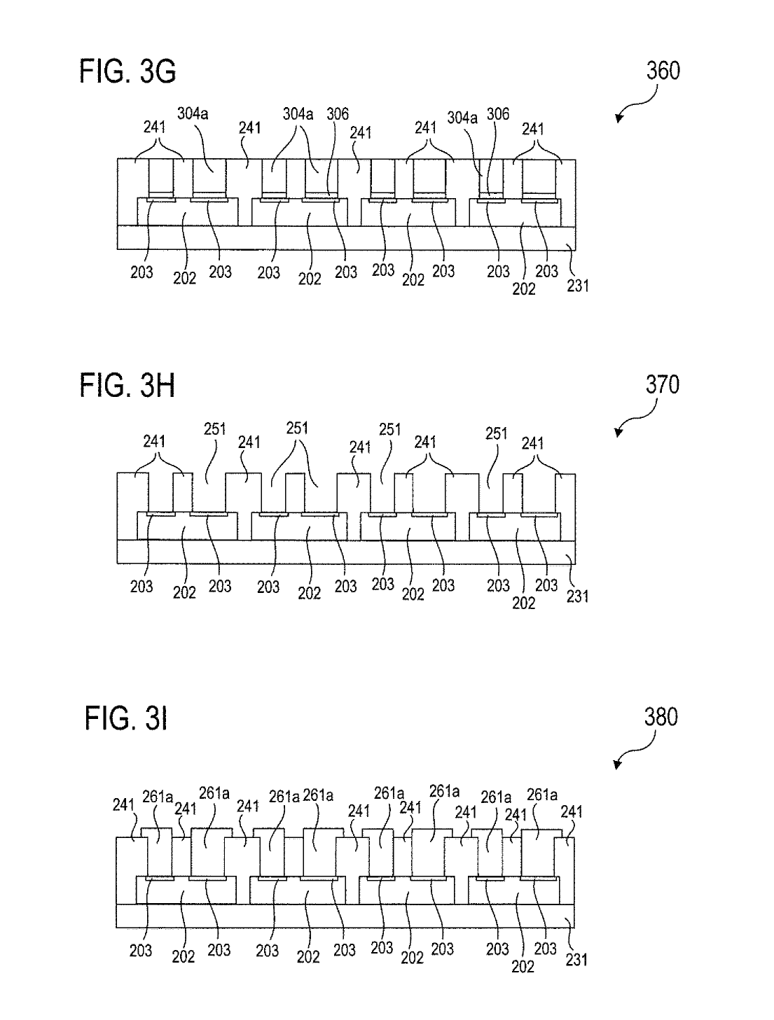

FIG. 3A to FIG. 3I show schematic cross-sectional views illustrating various processing stages in a method of processing at least one die in accordance with another embodiment.

FIG. 3A shows, in a view 300, that an adhesive polymer foil 307 may be provided, the foil including a carrier layer 305, a polymer layer 304 disposed on the carrier layer 305 and an adhesive layer 306 disposed on the polymer layer 304. The polymer layer 304 may serve as a placeholder element layer to form one or more placeholder elements (or spacers), as described below, and may have the thickness of the placeholder elements to be formed later.

FIG. 3B shows, in a view 310, that placeholder elements 304a (also referred to as spacers) may be formed from the placeholder element layer (i.e. the polymer layer 304) of the foil 307 by patterning the placeholder element layer (polymer layer 304). In accordance with some embodiments, the placeholder elements 304a may, for example, be formed by means of lasing (in other words, using a laser), or by means of a photolithographical process (in case the polymer material of the polymer layer 304 is a photopatternable material). To this end, the remaining polymer material around the placeholder elements 304a may be removed, as shown.

It should be noted that the patterning of the placeholder element layer (polymer layer 304) may be carried in such a manner that the locations and/or size of the placeholder elements 304a matches to locations and/or sizes of contact pads 203 of one or more dies 202, to which the placeholder elements 304a may be attached later, as described below.

FIG. 3C shows, in a view 320, that a wafer 201 including a plurality of dies 202, each die including one or more contact pads 203, may be provided and that the polymer foil 307 with the placeholder elements 304a may be applied to the wafer 201 such that the placeholder elements 304a may be attached to the contact pads 203 (by means of the adhesive layer 306). Illustratively, the placeholder elements 304a of the foil 307 may be transferred to the wafer 201. In accordance with some embodiments, the wafer 201 may, for example, be attached to a wafer carrier 321 (e.g. a glass carrier in accordance with an embodiment, or a sawing foil in accordance with another embodiment, alternatively any other suitable wafer carrier), e.g. by means of an adhesive layer 322, as shown.

FIG. 3D shows, in a view 330, that the carrier layer 305 of the foil 307 may be removed such that the placeholder elements (spacers) 304a remain over the contact pads 203. Clearly, the placeholder elements 304a may be located precisely at the locations where a metallization or terminal contacts may be formed later.

FIG. 3E shows, in a view 340, that the dies 202 may be singulated after the placeholder elements 304a have been formed. In other words, a die singulation process (also referred to as dicing) may be carried out to separate the dies 202 after the placeholder elements 304a have been formed. Clearly, in accordance with the embodiment shown, the placeholder elements 304a may be formed at a wafer level processing stage before singulation of the dies 202.

FIG. 3F shows, in a view 350, that the singulated dies 202 may be attached (in other words, mounted) to a carrier 231 (also referred to as die carrier), for example by means of an adhesive layer (not shown, see e.g. layer 232 in FIG. 2D), or by means of soldering, or using some other suitable die attaching technique. The carrier 231 may, for example, include or may be made of an electrically conductive material. For example, in accordance with some embodiments, the carrier 231 may be a metal carrier or metal plate, e.g. a lead frame, in accordance with some embodiments. In accordance with other embodiments, the carrier 231 may include or may be made of an electrically insulating material.

FIG. 3G shows, in a view 360, that a die embedding layer 241 may be formed such that the dies 202 and the placeholder elements 304a may be at least partially embedded in the die embedding layer 241. In accordance with various embodiments, the die embedding layer 241 may include or may be made of a suitable embedding material such as, for example, a laminate material, or a mold compound in accordance with another embodiment, or any other suitable embedding material in accordance with other embodiments. For example, in accordance with an embodiment, the die embedding layer 241 may be a foil that may be laminated onto the carrier 231 and the dies 202. The die embedding layer 241 may be formed such that an upper surface of the placeholder elements 304a is exposed, as shown.

In the embodiment shown in FIG. 3G, the die embedding layer 241 is shown such that an upper surface of the die embedding layer 241 is flush with an upper surface of the placeholder elements 304a. In this context it has to be noted that, in accordance with some embodiments, it may be possible that the die embedding layer 241 is initially formed such that it may cover the upper surface of the placeholder elements 304a, and that a part of the die embedding layer 241 that covers the upper surface of the placeholder elements 304a may subsequently be removed (e.g. using a laser or etch chemistry, alternatively using other suitable processes) to expose the upper surface of the placeholder elements 304a.

FIG. 3H shows, in a view 370, that the placeholder elements 304a (and the adhesive layer 306) may be removed (for example, by means of a selective etch process in accordance with an embodiment) such that openings 251 may be formed in the die embedding layer 241. The openings (or holes) 251 may be located above the contact pads 203 of the dies 202 such that the contact pads 203 may be exposed, as shown. In other words, the locations of the openings (holes) 251 may correspond to the locations of the contact pads 203.

FIG. 3I shows, in a view 380, that terminal contacts 261a may be formed that may electrically contact the contact pads 203. As shown, each contact pad 203 may be contacted by a respective terminal contact 261a, and the terminal contacts 261a may be separated from one another. The terminal contacts 261a may, for example, be formed by filling the openings 251 with a layer of electrically conductive material (e.g. a metal such as, for example, copper), for example by means of galvanic deposition or by introducing a metal paste (alternatively, by means of some other suitable process), and patterning the electrically conductive material (e.g. by means of a photolithographical etch process), for example similarly as shown in FIG. 2G and FIG. 2H. Illustratively, FIG. 3I shows a die arrangement in accordance with another embodiment.

In accordance with some embodiments, the dies 202 may subsequently be singulated. The singulated dies may, for example, be connected to a circuit board via the terminal contacts 261a and, in accordance with some embodiments, via additional electrical contacts (not shown, see e.g. FIG. 4F) formed over the carrier 231 between the dies 202 or next to the dies 202. In accordance with some embodiments, the additional electrical contacts may, for example, be formed by forming additional placeholder elements over the carrier 231 between the dies or next to the dies 202 (e.g. after attaching the dies 202 to the carrier 231), forming the die embedding layer 241 to additionally embed the additional placeholder elements, removing the additional placeholder elements to form additional openings over the carrier 231, filling the additional openings with the layer 261 of electrically conductive material and patterning the layer 261 accordingly (not shown, compare FIG. 4B to FIG. 4F).

Similarly to the embodiment shown in FIG. 2A to 2H, the placeholder elements 304a may clearly be formed at a wafer level processing stage in accordance with the embodiment shown in FIG. 3A to FIG. 3I.

FIG. 4A to FIG. 4F show schematic cross-sectional views illustrating various processing stages in a method of processing at least one die in accordance with another embodiment.

FIG. 4A shows, in a view 400, that a carrier 231 (also referred to as die carrier) with a plurality of dies 202 mounted on the carrier 231 may be provided. In accordance with some embodiments, the carrier 231 may include or may be made of electrically conductive material. For example, in accordance with some embodiments, the carrier 231 may be a metal plate, e.g. a lead frame. In accordance with other embodiments, the carrier 231 may be a different suitable carrier. The dies 202 may be attached to the carrier 231, for example, by means of an adhesive layer 232 (as shown), or by means of soldering, or using some other suitable die attaching technique. Each die 202 may include one or more contact pads 203, as shown. The contact pads 203 may be configured in accordance with one or more embodiments described herein.

FIG. 4B shows, in a view 410, that placeholder elements 404a (also referred to as spacers) may be formed over the contact pads 203 of the dies 202.

In accordance with some embodiments, additional placeholder elements 404b (also referred to as additional spacers) may be formed over the carrier 231, for example between the dies 202 or next to the dies 202, as shown.

The placeholder elements 404a and the additional placeholder elements 404b (if provided) may be formed such that their height and/or thickness may be equivalent to the height and/or thickness of a later contact metallization.

In accordance with some embodiments, the placeholder elements 404a and/or the additional placeholder elements 404b (if provided) may be formed by means of an adhesive material. In accordance with some embodiments, the adhesive material may, for example, be an adhesive that may lose its adhesive force again at higher temperatures, in other words at temperatures that are higher than a certain temperature threshold, (e.g. at temperatures higher than about 150° C. in accordance with an embodiment, although other temperature thresholds may be possible as well). In other words, the adhesive may be configured as a so-called thermal release adhesive. This may allow for relatively easy removal of the placeholder elements 404a and/or additional placeholder elements 404b by heating, as described below. In accordance with other embodiments, the adhesive material may, for example, be an adhesive that may lose its adhesive force again upon exposure to light (e.g. UV light) (so-called light release adhesive), which may also allow for relatively easy removal of the placeholder elements 404a and/or additional placeholder elements 404b, as described herein.

In accordance with some embodiments, the adhesive material of the placeholder elements 404a and/or additional placeholder elements 404b may, for example, be applied to the contact pads 203 and/or carrier 231 by means of dispensing. Alternatively, the adhesive material may be applied using other suitable techniques.

FIG. 4C shows, in a view 420, that a die embedding layer 241 may be formed. The die embedding layer 241 may be formed such that it embeds at least partially the dies 202 and the placeholder elements 404a and the additional placeholder elements 404b (if provided). Clearly, the die embedding layer 241 may fill the gaps between the dies 202 and the placeholder elements 404a and additional placeholder elements 404b. In accordance with some embodiments, the die embedding layer 241 may, for example, be formed by means of a lamination process. Illustratively, in accordance with some embodiments, the plurality of dies 202 mounted to the die carrier 231 and the placeholder elements 404a and additional placeholder elements 404b may be laminated into a lamination layer (e.g. a foil). Alternatively, the die embedding layer 241 may be formed using other suitable processes such as, for example, molding.

In the embodiment shown in FIG. 4C, the die embedding layer 241 is shown such that an upper surface of the die embedding layer 241 is flush with an upper surface of the placeholder elements 404a and additional placeholder elements 404b. In this context it has to be noted that, in accordance with some embodiments, it may be possible that the die embedding layer 241 is initially formed such that it may cover the upper surface of the placeholder elements 404a and/or additional placeholder elements 404b, and that a part of the die embedding layer 241 that covers the upper surface of the placeholder elements 404a and/or additional placeholder elements 404b may subsequently be removed again to expose the upper surface of the placeholder elements 404a and/or additional placeholder elements 404b.

FIG. 4D shows, in a view 430, that the placeholder elements 404a and the additional placeholder elements 404b may be removed, for example by means of heating the carrier 231 with the dies 202 including the placeholder elements 404a and the additional placeholder elements 404b above a given temperature threshold, e.g. above about 150° C. in accordance with an embodiment (other temperature thresholds may be possible in accordance with other embodiments), (e.g. in case the placeholder elements 404a and/or the additional placeholder elements 404b are made of a thermal release adhesive), or by exposing the placeholder elements 404a and the additional placeholder elements 404b to light (e.g. UV light) (e.g. in case the placeholder elements 404a and/or the additional placeholder elements 404b are made of a light release adhesive). In accordance with some embodiments, the die carrier 231 with the dies 202 mounted thereon may be rotated, for example by about 180 degrees such that the dies 202 may be clearly oriented “upside down”, so that the placeholder elements 404a and the additional placeholder elements 404b may slip out of the die embedding layer 241.

Removing the placeholder elements 404a and the additional placeholder elements 404b may result in openings (or holes) 251 located above the contact pads 203, and additional openings (or holes) 251′ located above the die carrier 231 between the dies 202 or next to the dies 202, as shown.

FIG. 4E shows, in a view 440, that the openings 251 and additional openings 251′ may be filled with a layer 261 of electrically conductive material, for example metal (e.g. copper), for example by means of galvanic deposition or by means of introducing a metal paste (alternatively, using other suitable techniques). Thus, the terminals (i.e. the contact pads 203) may be electrically contacted.

FIG. 4F shows, in a view 450, that the layer 261 may be patterned such that separate terminal contacts (“vias”) 261a may be formed over the contact pads 203 of the dies 202 (as shown, a single terminal contact 261a may in each case be formed over a respective one of the contact pads 203 in accordance with some embodiments) and additional electrical contacts 261b may be formed over the die carrier 231 between the dies 202 or next to the dies 202, as shown. In accordance with some embodiments, the die carrier 231 may be configured as electrically conductive carrier (e.g. as a metal plate or lead frame in accordance with some embodiments) and the additional electrical contacts 261b may thus serve to electrically contact the back side of the dies 202 via the die carrier 231 (while the terminal contacts 261a may serve to electrically contact the contact pads 203 on the front side of the dies 202). Patterning the layer 261 may, for example, be achieved by means of a photolithographic etch process in accordance with some embodiments. Illustratively, FIG. 4F shows a die arrangement in accordance with another embodiment.

In accordance with some embodiments, the dies 202 may subsequently be singulated. The singulated dies may, for example, be connected to a circuit board via the terminal contacts 261a and the additional electrical contacts 261b.

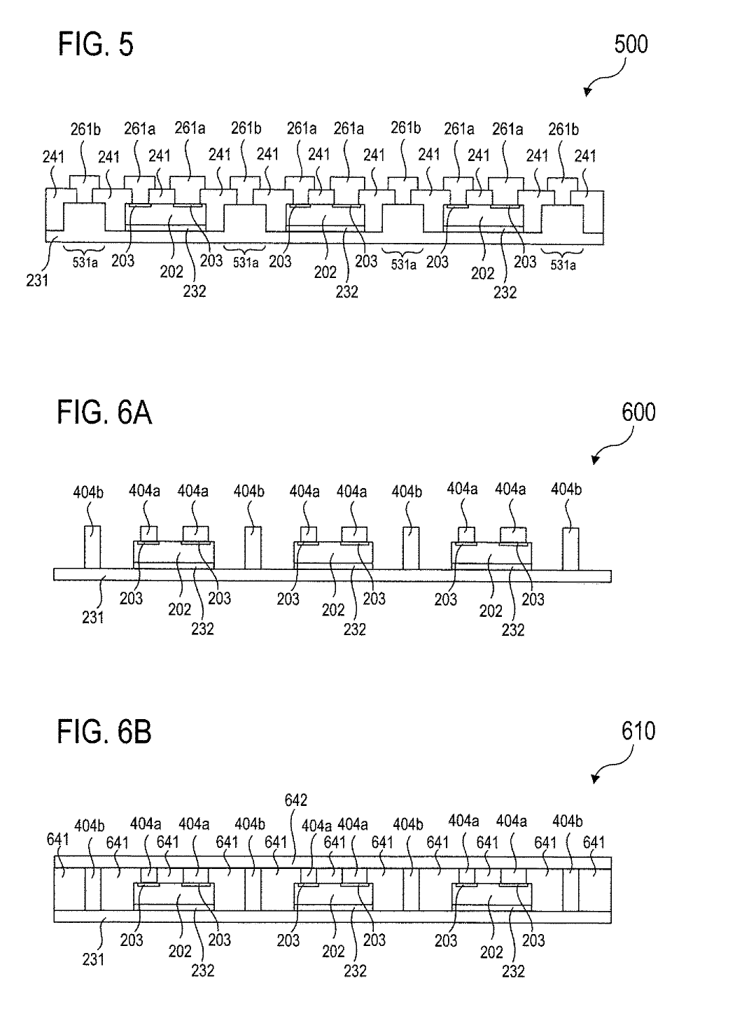

FIG. 5 shows, in a schematic cross-sectional view, a die arrangement 500 in accordance with another embodiment. The die arrangement includes a plurality of dies 202 and may be obtained by a method of processing at least one die in accordance with another embodiment.

The die arrangement 500 may be similar to the die arrangement shown in FIG. 4F (in particular, the same reference signs may denote the same elements as there and will not be described again here for sake of brevity), with the difference that the die carrier 231 includes portions or sections 531a having a greater thickness than other portions or sections of the die carrier 231, as shown. The locations of the portions 531a with greater thickness may correspond to the locations of the additional electrical contacts 261b. In other words, the additional electrical contacts 261b may be located over the portions 531a of the die carrier 231 having the larger thickness.

The die arrangement 500 shown in FIG. 5 may, for example, be obtained in a similar manner as described in connection with FIG. 4A to FIG. 4F, wherein the additional placeholder elements 404b (that define the positions of the later-formed additional electrical contacts 261b) may be formed over the portions 531a of the die carrier 231 having the greater thickness.

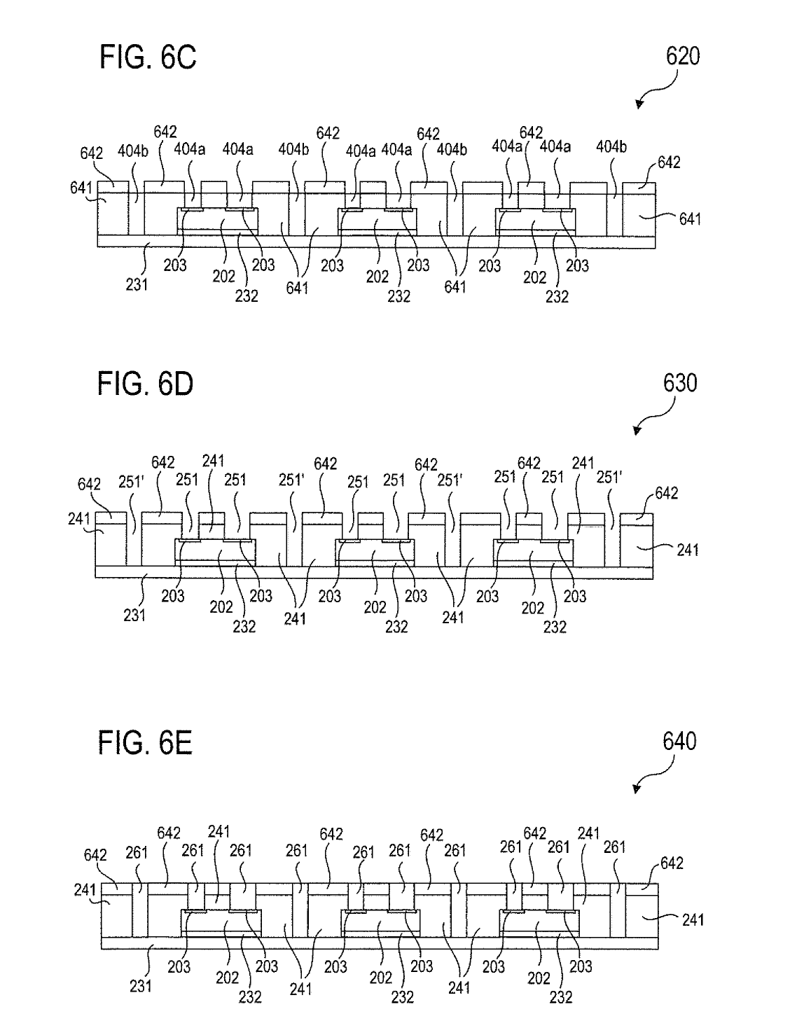

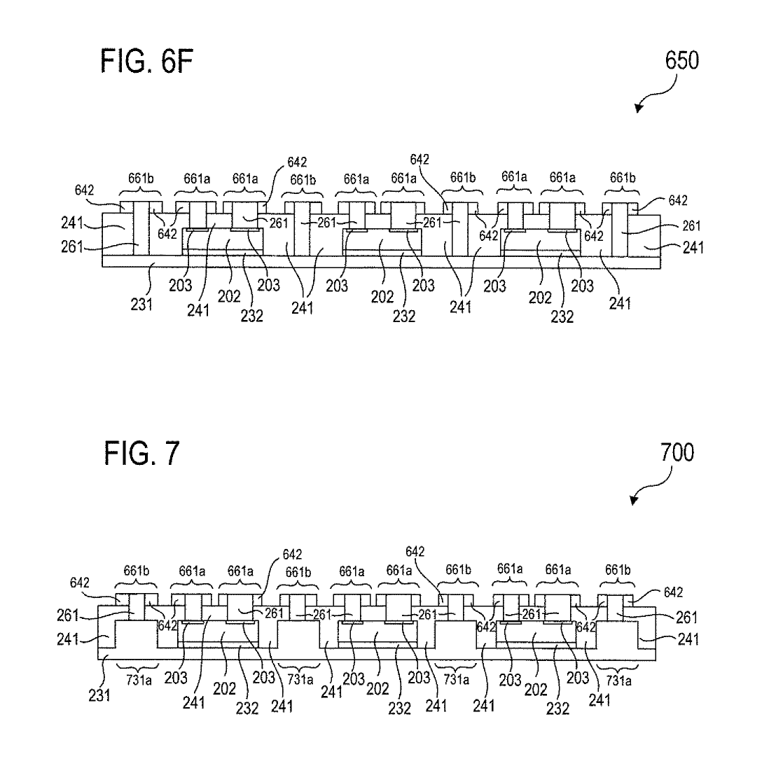

FIG. 6A to FIG. 6G show schematic cross-sectional views illustrating various processing stages in a method of processing at least one die in accordance with another embodiment.

FIG. 6A shows, in a view 600, that a die carrier 231 with a plurality of dies 202 attached to the die carrier 231 (e.g. via an adhesive layer 232, as shown) may be provided, and a plurality of placeholder elements (or spacers) 404a may be formed over contact pads 203 of the dies 202, and additional placeholder elements (or spacers) 404b may be formed over the die carrier 231 between the dies 202 or next to the dies 202. This may, for example, be achieved in the same or a similar manner as described above in connection with FIG. 4A and FIG. 4B and will not be described in detail again here for sake of brevity.

FIG. 6B shows, in a view 610, that a laminate layer 641 with a thin metal layer 642 applied to the laminate layer 641 (e.g., in accordance with an embodiment, layers 641 and 642 may be an RCC (“resin coated copper”)) may be used to at least partially embed the plurality of dies 202 attached to the die carrier 231, the placeholder elements 404a formed over the dies' contact pads 203 and the additional placeholder elements 404b formed over the die carrier 231. As shown, the laminate layer 641 and metal layer 642 (e.g. RCC) may be applied such that an upper surface of the laminate layer 641 is flush with an upper surface of the placeholder elements 404a and the additional placeholder elements 404b, in accordance with some embodiments.

FIG. 6C shows, in a view 620, that the metal layer 642 may be removed (for example, using a photolithographic process) above the placeholder elements 404a and above the additional placeholder elements 404b to expose the placeholder elements 404a and the additional placeholder elements 404b.

FIG. 6D shows, in a view 630, that the placeholder elements 404a and the additional placeholder elements 404b may be removed, for example by heating the placeholder elements 404a and the additional placeholder elements 404b in case the placeholder elements 404a and the additional placeholder elements 404b include or are made of a thermally deactivatable material (e.g. thermal release adhesive), for example to a temperature above approximately 150° C. in accordance with an embodiment, or by exposing the placeholder elements 404a and the additional placeholder elements 404b to light (e.g. UV light) in case the placeholder elements 404a and the additional placeholder elements 404b include or are made of a material whose adhesive force may be reduced by exposure to light (e.g. UV light), in accordance with another embodiment. In addition, the die carrier 231 with the plurality of dies 202 attached may be rotated, e.g. such that the arrangement is oriented “upside down”, to achieve that the placeholder elements 404a and the additional placeholder elements 404b may slip out, in accordance with some embodiments.

Thus, openings 251 may be formed over the contact pads 203 and additional openings 251′ may be formed over the die carrier 231 between the dies 202 or next to the dies 202, similarly as described above in connection with FIG. 4D, so that the contact pads 203 may be exposed at those locations where the placeholder elements 404a were located and the die carrier 231 may be exposed at those locations where the additional placeholder elements 404b were located.

FIG. 6E shows, in a view 640, that the openings 251 and the additional openings 251′ may be filled with electrically conductive material 261 (e.g. metal), for example by means of galvanic deposition or by introducing a metal paste (alternatively, using other suitable techniques), so that the contact pads 203 may be contacted by the electrically conductive material 261 and the die carrier 231 may also be contacted by the electrically conductive material 261.

FIG. 6F shows, in a view 650, that the metal layer 642 may be patterned such that separate terminal contacts (“vias”) 661a may be formed over the contact pads 203 of the dies 202 (as shown, a single terminal contact 661a may in each case be formed over a respective one of the contact pads 203 in accordance with some embodiments) and additional electrical contacts 661b may be formed over the die carrier 231 between the dies 202 or next to the dies 202, as shown. In accordance with some embodiments, the die carrier 231 may be configured as electrically conductive carrier (e.g. as a metal plate or lead frame in accordance with some embodiments) and the additional electrical contacts 661b may thus serve to electrically contact the back side of the dies 202 via the die carrier 231 (while the terminal contacts 661a may serve to electrically contact the contact pads 203 on the front side of the dies 202). Patterning the metal layer 642 may, for example, be achieved by means of a photolithographic etch process in accordance with some embodiments. Illustratively, FIG. 6F shows a die arrangement in accordance with another embodiment.

In accordance with some embodiments, the dies 202 may subsequently be singulated. The singulated dies may, for example, be connected to a circuit board via the terminal contacts 661a and the additional electrical contacts 661b.

FIG. 7 shows, in a schematic cross-sectional view 700, a die arrangement 700 in accordance with another embodiment. The die arrangement 700 includes a plurality of dies 202 and may be obtained by a method of processing at least one die in accordance with another embodiment.

The die arrangement 700 may be similar to the die arrangement shown in FIG. 6F (in particular, the same reference signs may denote the same elements as there and will not be described again here for sake of brevity), with the difference that the die carrier 231 includes portions or sections 731a having a greater thickness than other portions or sections of the die carrier 231, as shown. The locations of the portions 731a with greater thickness may correspond to the locations of the additional electrical contacts 661b. In other words, the additional electrical contacts 661b may be located over the portions 731a of the die carrier 231 having the larger thickness.

The die arrangement 700 shown in FIG. 7 may, for example, be obtained in a similar manner as described in connection with FIG. 6A to FIG. 6F, wherein the additional placeholder elements 404b (that define the positions of the later-formed additional electrical contacts 661b) may be formed over the portions 731a of the die carrier 231 having the greater thickness.

In the following, exemplary features and potential effects of exemplary embodiments described herein are discussed.

In accordance with various embodiments, one or more placeholder elements (herein also referred to as “placeholder structures” or, short, “placeholders”, or as “spacers”), e.g. columns with cylindrical shapes (alternatively, any other shape may be possible), may be formed (e.g. deposited) temporarily over one or more contact pads of a die (or a plurality of dies) and, in accordance with some embodiments, possibly also over a carrier, to which the die may be attached (e.g. a metal carrier or metal plate, e.g. a lead frame). The one or more placeholder elements may be removed again (e.g. by heating in accordance with some embodiments, or with the aid of a magnet in accordance with some embodiments) after a die embedding layer has been formed (e.g. by means of a lamination process). Thus, one or more openings (holes) may be formed over the one or more contact pads that may enable metallization of the die, in other words electrically contacting the one or more contact pads of the die by means of electrically conductive material (e.g. metal).

In accordance with various embodiments, one or more temporary placeholder elements (e.g. columns) may be applied to one or more contact pads of one or more dies (chips) and, possibly, to a carrier (e.g. metal carrier or metal plate, e.g. lead frame), e.g. after die-bonding the die or dies (chips) to the carrier in accordance with some embodiments, or still at a wafer level processing stage in accordance with some embodiments. The placeholder element(s) may, for example, have a diameter and/or length that may correspond to the diameter and/or length of a later contact metalllization.

In accordance with various embodiments, a die embedding layer may be formed after formation of the placeholder elements, for example by means of a standard lamination process in accordance with some embodiments.

In accordance with various embodiments, the temporary placeholder elements (e.g. columns) may be removed again after formation of the die embedding layer. Thus, openings or holes may remain at those locations where the placeholder elements were located.

In accordance with some embodiments, the temporary placeholder elements (e.g. columns) may, for example, be removed by selective etching, or by heating, or by exposing to light (e.g. UV light).

In accordance with various embodiments, the openings or holes may be filled with contact material (e.g. contact metal). Thus, a metallization of the holes may be achieved. Thus, terminal contacts (“vias”) may be realized.

In accordance with various embodiments, the one or more placeholder elements (e.g. columns) may include or may be made of a material that may be removed easily, for example without leaving residues on the material of the die embedding layer to be formed later.

In accordance with one embodiment, the one or more placeholder elements (e.g. columns) may be formed, for example, by means of a thermally deactivatable adhesive, in other words an adhesive that may lose its adhesive force at least partially upon heating, herein also referred to as thermal release adhesive. This may facilitate a later removal of the one or more placeholder elements.

In accordance with another embodiment, the one or more placeholder elements (e.g. columns) may be formed, for example, by means of an adhesive that may be deactivated by light (e.g. UV light), in other words an adhesive that may lose its adhesive force at least partially upon exposure to light, herein also referred to as light release adhesive (e.g. UV release adhesive). This may facilitate a later removal of the one or more placeholder elements.

In accordance with still another embodiment, the one or more placeholder elements (e.g. columns) may include or may be made of a magnetic material (e.g. a paramagnetic or ferromagnetic material, e.g. a metal or metal alloy, e.g. a ferrous material, e.g. steel). This may allow removal of the one or more placeholder elements with the aid of a magnet. For example, a plurality of placeholder elements may be easily removed in parallel by means of a magnet.

In accordance with still another embodiment, the one or more placeholder elements (e.g. columns) may include or may be made of a plastic material (e.g. a UV transparent plastic material).

In accordance with some embodiments, the one or more placeholder elements (e.g. columns) may be made of an anti-stick material or may include an anti-stick coating of anti-stick material such as polytetrafluoroethylene (PTFE) (“Teflon”). For example, in accordance with some embodiments the one or more placeholder elements may be made of PTFE, or of steel coated with PTFE, or of a UV transparent plastic material with an anti-stick coating such as PTFE, although other implementations may be possible as well. Thus, sticking of the placeholder element to the material of the die embedding layer to be formed later may be reduced or avoided. This may facilitate a later removal of the one or more placeholder elements.

In accordance with various embodiments, terminal contacts (“vias”) may be realized in a chip embedding technology without the need to bore holes into the chip embedding material (e.g. laminate), for example by means of a laser. Clearly, in accordance with various embodiments, holes may instead be formed in the chip embedding material by forming placeholder elements (or spacers) before depositing the chip embedding material and removing the placeholder elements (or spacers) after deposition of the chip embedding material.

This may have the effect that damage of a front side metallization of a chip (which may, for example, occur in laser boring if the focusing depth of the laser is set incorrectly) may be avoided in accordance with various embodiments. Thus, chips with thinner metallizations (for example, Cu metallizations having a thickness of less than 5 μm) on the chip front side may be realized in accordance with various embodiments.

Another effect may be that metallization edges of the filled vias may be defined by the placeholders and may thus be smoother compared to vias that are realized by means of hole boring. For example, a surface roughness of the metallization edges may be equal to or less than about 5 μm in accordance with some embodiments, for example equal to or less than about 1 μm in accordance with some embodiments; other values of the surface roughness may be possible as well in accordance with other embodiments.

Another effect may be that a plurality of openings or holes may be formed in a die embedding layer at the same time in accordance with various embodiments. In other words, the openings or holes may be formed in parallel, which may be faster compared to a serial process such as serial laser boring.

In accordance with various embodiments, terminal contacts (“vias”) may be aligned more precisely to contact pads of a die, as front-end processing steps with very high positioning accuracy may be exploited to form holes in the die embedding material above the contact pads. Thus, in accordance with various embodiments chips may be realized, in which terminal contacts may utilize a higher percentage of the contact pad area. For example, in accordance with some embodiments, dies may be realized, in which a terminal contact may utilize up to 100% of the area of a respective contact pad, e.g. 70% to 100% in accordance with some embodiments, e.g. 80% or more in accordance with some embodiments, e.g. 90% or more in accordance with some embodiments, without protruding over the contact pad area.

A method of processing at least one die in accordance with some embodiments may include: forming at least one placeholder element over at least one contact pad of at least one die; forming a die embedding layer to at least partially embed the at least one die and the at least one placeholder element; removing the at least one placeholder element to form at least one opening in the die embedding layer and expose the at least one contact pad of the at least one die; filling the at least one opening with electrically conductive material to electrically contact the at least one contact pad of the at least one die.

In accordance with some embodiments, the contact pad may include or may be made of metal (e.g. copper or aluminum) or a metal alloy (e.g. an alloy containing copper and/or aluminum).

In accordance with some embodiments, the at least one placeholder element may include a material that may be removed without leaving residues on the die embedding layer.

In accordance with some embodiments, the placeholder element may include at least one material selected from a group of materials consisting of: polytetrafluoroethylene (PTFE); a UV transparent plastic material; a ceramic material; a thermally deactivatable adhesive; an adhesive that may be deactivated by light; a magnetic material.

In accordance with some embodiments, the at least one placeholder element may include an anti-stick coating.

In accordance with some embodiments, the placeholder element may have the shape of a column or pillar. The column may, for example, have an elliptical, circular or polygonal (e.g. rectangular, quadratic, triangular, hexagonal, etc.) cross-section. The diameter and/or height of the column may, for example, correspond to the diameter and/or height of a terminal contact to be formed later.

In accordance with some embodiments, forming the at least one placeholder element may be carried out at a wafer level processing stage.

In accordance with some embodiments, forming the at least one placeholder element may include: forming (e.g. depositing) a placeholder element layer over the at least one die, and patterning the placeholder element layer to form the at least one placeholder element.

In accordance with some embodiments, the placeholder element layer may include a photopatternable layer.

In accordance with some embodiments, the photopatternable layer may include a photopatternable polymer material (e.g. a photoresist).

In accordance with some embodiments, patterning the placeholder element layer may be effected using a photolithographic process.

In accordance with some embodiments, patterning the placeholder element layer may be effected using a laser.

In accordance with some embodiments, the die may be part of a wafer that includes a plurality of dies, and forming the placeholder element layer over the die may include forming the placeholder element layer over the wafer.

In accordance with some embodiments, the wafer may be diced after patterning the placeholder element layer.

In accordance with some embodiments, forming the at least one placeholder element may include: providing a carrier layer and a placeholder element layer disposed over the carrier layer; patterning the placeholder element layer to have the at least one placeholder element; applying the carrier layer with the patterned placeholder element layer to the at least one die to transfer the at least one placeholder element onto the at least one contact pad of the at least one die; removing the carrier layer.

In accordance with some embodiments, the die may be part of a wafer that includes a plurality of dies, and applying the carrier layer with the patterned placeholder element layer to the at least one die may include applying the carrier layer with the patterned placeholder element layer to the wafer.

In accordance with some embodiments, the wafer may be diced after removing the carrier layer.

In accordance with some embodiments, forming the at least one placeholder element may be carried out at a package level processing stage.

In accordance with some embodiments, forming the at least one placeholder element may be effected by means of dispensing placeholder element material over the at least one contact pad.

In accordance with some embodiments, forming the at least one placeholder element may be effected using a screen printing process.

In accordance with some embodiments, forming the at least one placeholder element may be effected using a lamination process.

In accordance with some embodiments, the die embedding layer may be formed using a lamination process. In accordance with some embodiments, the die embedding layer may be formed by molding. Alternatively, the die embedding layer may be formed using other suitable processes.

In accordance with some embodiments, the die embedding layer may include or may be made of a laminate material (e.g. an epoxy resin in accordance with some embodiments). In accordance with some embodiments, the die embedding layer may include or may be made of a mold compound.

In accordance with some embodiments, the die embedding layer may include or may be a laminate layer (e.g. a laminate foil in accordance with some embodiments, or a resin coated copper (RCC) in accordance with some embodiments).

In accordance with some embodiments, the at least one placeholder element may include or may be made of a thermally deactivatable adhesive, and removing the at least one placeholder element may include heating the at least one placeholder element (for example up to a temperature where the thermally deactivatable adhesive substantially loses its adhesive force, e.g. to a temperature equal to or greater than about 150° C. in accordance with some embodiments).

In accordance with some embodiments, removing the at least one placeholder element may further include orienting the die such that the at least one placeholder element may slip out of the die embedding layer (e.g. assisted by or due to gravity).

In accordance with some embodiments, the at least one placeholder element may include or may be made of an adhesive that may be deactivated by light, and removing the at least one placeholder element may include exposing the at least one placeholder element to light (e.g. UV light in accordance with some embodiments).

In accordance with some embodiments, the at least one placeholder element may include or may be made of a magnetic material, and removing the at least one placeholder element may be effected using a magnet.

In accordance with some embodiments, removing the at least one placeholder element may be effected by means of a selective etch process.

In accordance with some embodiments, the electrically conductive material may include or may be a metal or a metal alloy (e.g. copper or a copper alloy in accordance with some embodiments).

In accordance with some embodiments, filling the at least one opening with the electrically conductive material may include or may be achieved by galvanic deposition of the electrically conductive material.

In accordance with some embodiments, filling the at least one opening with the electrically conductive material may include or may be achieved by introducing a metal paste into the at least one opening.

In accordance with some embodiments, the at least one die may be attached to a die carrier, and the method may further include: forming at least one additional placeholder element over the die carrier before forming the die embedding layer, wherein forming the die embedding layer may include forming the die embedding layer such that it additionally embeds the at least one additional placeholder element at least partially; removing the at least one additional placeholder element to form at least one additional opening in the die embedding layer over the die carrier; and filling the at least one additional opening with the electrically conductive material to electrically contact the die carrier.

In accordance with some embodiments, the die carrier may be a metal plate (e.g. a lead frame in accordance with some embodiments).

A method of processing a plurality of dies in accordance with some embodiments may include: providing a wafer including a plurality of dies, each die including at least one contact pad; forming a placeholder element layer over the wafer to cover the plurality of dies; patterning the placeholder element layer to form a plurality of placeholder elements over the contact pads of the dies; forming a die embedding layer over the plurality of dies to at least partially embed the dies and the placeholder elements; removing the placeholder elements to form openings in the die embedding layer and expose the contact pads of the dies; filling the openings with electrically conductive material to electrically contact the contact pads of the dies.

In accordance with some embodiments, before forming the die embedding layer, the wafer may be diced to singulate the plurality of dies and the singulated dies may be applied to a die carrier.

In accordance with some embodiments, the placeholder element layer may include or may be a photopatternable polymer layer.

A die arrangement in accordance with some embodiments may include: at least one die including at least one contact pad; at least one terminal contact disposed over the at least one contact pad of the at least one die; a die embedding layer at least partially embedding the at least one die and the at least one terminal contact; wherein the at least one terminal contact may have been formed by forming at least one placeholder element over the at least one contact pad of the at least one die, forming the die embedding layer to at least partially embed the at least one die and the at least one placeholder element, removing the at least one placeholder element to form at least one opening in the die embedding layer and expose the at least one contact pad of the at least one die, and filling the at least one opening with electrically conductive material to electrically contact the at least one contact pad of the at least one die.

In accordance with some embodiments, the die embedding layer may be free from carbon black particles.

In accordance with some embodiments, an interface between the at least one terminal contact and the die embedding layer, which corresponds to a sidewall or sidewalls of the at least one opening formed in the die embedding layer, may have a surface roughness of equal to or less than about 5 μm (e.g. equal to or less than about 1 μm in accordance with some embodiments).

A method of processing a die in accordance with some embodiments may include: forming at least one placeholder element on or above at least one contact pad of a die; forming an embedding layer such that the die and the at least one placeholder element are at least partially embedded in the embedding layer; removing the at least one placeholder element from the at least one contact pad such that at least one opening is formed in the embedding layer above the at least one contact pad; filling the at least one opening with electrically conductive material such that the at least one contact pad is electrically contacted by the electrically conductive material.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of processing at least one die, the method comprising:
forming at least one placeholder element over at least one contact pad of at least one die;
forming a die embedding layer to at least partially embed the at least one die and the at least one placeholder element;
removing the at least one placeholder element to form at least one opening in the die embedding layer and expose the at least one contact pad of the at least one die;
filling the at least one opening with electrically conductive material to electrically contact the at least one contact pad of the at least one die.

2. The method of claim 1, wherein the at least one placeholder element comprises a material that may be removed without leaving residues on the die embedding layer.

3. The method of claim 1, wherein the placeholder element comprises at least one material selected from a group of materials consisting of:
polytetrafluoroethylene (PTFE);
a UV transparent plastic material;
a ceramic material;
a thermally deactivatable adhesive;
an adhesive that may be deactivated by light;
a magnetic material.

4. The method of claim 1, wherein the at least one placeholder element comprises an anti-stick coating.

5. The method of claim 1, wherein forming the at least one placeholder element is carried out at a wafer level processing stage.

6. The method of claim 1, wherein forming the at least one placeholder element comprises:
forming a placeholder element layer over the at least one die;
patterning the placeholder element layer to form the at least one placeholder element.

7. The method of claim 6, wherein the placeholder element layer comprises a photopatternable layer.

8. The method of claim 1, wherein forming the at least one placeholder element comprises:
providing a carrier layer and a placeholder element layer disposed over the carrier layer;
patterning the placeholder element layer to have the at least one placeholder element;
applying the carrier layer with the patterned placeholder element layer to the at least one die to transfer the at least one placeholder element onto the at least one contact pad of the at least one die;
removing the carrier layer.

9. The method of claim 1, wherein forming the at least one placeholder element is carried out at a package level processing stage.

10. The method of claim 1, wherein forming the at least one placeholder element is effected by means of dispensing placeholder element material over the at least one contact pad.

11. The method of claim 1, wherein forming the at least one placeholder element is effected using a screen printing process.

12. The method of claim 1, wherein forming the at least one placeholder element is effected using a lamination process.

13. The method of claim 1, wherein the die embedding layer is formed using a lamination process.

14. The method of claim 1, wherein the die embedding layer comprises a mold compound.

15. The method of claim 1, wherein the at least one placeholder element comprises a thermally deactivatable adhesive and wherein removing the at least one placeholder element comprises heating the at least one placeholder element.

16. The method of claim 1, wherein the at least one placeholder element comprises an adhesive that may be deactivated by light, and wherein removing the at least one placeholder element comprises exposing the placeholder element to light

17. The method of claim 1, wherein the at least one placeholder element comprises a magnetic material, and wherein removing the at least one placeholder element is effected using a magnet.

18. The method of claim 1, wherein removing the at least one placeholder element is effected by means of a selective etch process.

19. The method of claim 1, wherein the die is attached to a die carrier, the method further comprising:
forming at least one additional placeholder element over the die carrier before forming the die embedding layer, wherein forming the die embedding layer comprises forming the die embedding layer such that it additionally embeds the at least one additional placeholder element at least partially;
removing the at least one additional placeholder element to form at least one additional opening in the die embedding layer over the die carrier;
filling the at least one additional opening with the electrically conductive material to electrically contact the die carrier.

20. The method of claim 18, wherein the die carrier comprises a metal plate.

21. A method of processing a plurality of dies, the method comprising:
providing a wafer comprising a plurality of dies, each die comprising at least one contact pad;
forming a placeholder element layer over the wafer to cover the plurality of dies;
patterning the placeholder element layer to form a plurality of placeholder elements over the contact pads of the dies;
forming a die embedding layer over the plurality of dies to at least partially embed the dies and the placeholder elements;
removing the placeholder elements to form openings in the die embedding layer and expose the contact pads of the dies;
filling the openings with electrically conductive material to electrically contact the contact pads of the dies.

22. The method of claim 21, further comprising:
dicing the wafer to singulate the plurality of dies and applying the singulated dies to a die carrier before forming the die embedding layer.

23. The method of claim 21, wherein the placeholder element layer comprises a photopatternable polymer layer.

24. A die arrangement, comprising:
at least one die comprising at least one contact pad;
at least one terminal contact disposed over the at least one contact pad of the at least one die;
a die embedding layer at least partially embedding the at least one die and the at least one terminal contact;
wherein the at least one terminal contact has been formed by forming at least one placeholder element over the at least one contact pad of the at least one die, forming the die embedding layer to at least partially embed the at least one die and the at least one placeholder element, removing the at least one placeholder element to form at least one opening in the die embedding layer and expose the at least one contact pad of the at least one die, and filling the at least one opening with electrically conductive material to electrically contact the at least one contact pad of the at least one die.

25. The die arrangement of claim 24, wherein the die embedding layer is free from carbon black particles.

26. The die arrangement of claim 24, wherein an interface between the at least one terminal contact and the die embedding layer, which corresponds to a sidewall of the at least one opening formed in the die embedding layer, has a surface roughness of equal to or less than about 5 μm.
